(19) United States
(12) Patent Application Publication
(10) Pub. No.: US 2026/0147071 A1
(43) Pub. Date: May 28, 2026

(54) NMR Measurement System

(71) Applicant: JEOL Ltd., Tokyo (JP)

(72) Inventors: Yoshiaki Yamakoshi, Tokyo (JP); Tomohisa Nonoyama, Tokyo (JP)

(21) Appl. No.: 19/398,486

(22) Filed: Nov. 24, 2025

(30) Foreign Application Priority Data
Nov. 25, 2024 (JP) 2024-204510

(51) Int. Cl. G01R 33/30

(52) U.S. Cl. CPC G01R 33/307

(57) ABSTRACT

A sample tube lock is disposed at a given position on the outer periphery of the sample tube. A holder has a central portion provided with a vertically extending insertion space into which the sample tube is inserted. The holder supports the sample tube lock. A rotor surrounds the sample tube lock and the sample tube and includes a groove formed in the vicinity of the inner surface of the holder. A holder lock includes a cylindrical sidewall, a top wall and a flange portion. The top wall extends inwardly from the top end of the cylindrical sidewall and has an insertion hole into which the sample tube is inserted. The flange portion extends outwardly from the outer periphery at the lower end of the sidewall. The outer peripheral portion of the flange portion is received in the groove and secured to the rotor.

### CROSS REFERENCE TO RELATED APPLICATION

This application claims priority to Japanese Patent Application No. 2024-204510 filed Nov. 25, 2024, the disclosure of which is hereby incorporated by reference in its entirety.

### BACKGROUND OF THE DISCLOSURE

### Field of the Disclosure

The present disclosure relates to an NMR (nuclear magnetic resonance) measurement system and, more particularly, to a holding structure for holding a sample tube that accommodates an NMR sample under investigation.

### Description of Related Art

In an NMR measurement system, a measurement is performed while a solution sample under investigation is sealed within an elongated sample tube.

Normally, a measurement can be carried out while rotating the sample tube. The sample tube is received in a cylindrical rotor. The sample tube extends downwardly from the rotor, and an NMR measurement is made of the portion of the sample received in the downwardly extending part of the sample tube by a detector arranged therearound. The detector has a sensitive area responsive to certain signals. In order to obtain optimum sensitivity, it is necessary to place the detector such that the sample is in maximum proximity to the sensitive area.

Therefore, the portion of the sample sealed in the sample tube is first accurately placed in position using a separately prepared gauge. The rotor in which the sample tube has been mounted is loaded on the detector by the principle of pneumatic floaters using flowing air.

Examples of the NMR measurement system are described in JP-A-2007-33110 and U.S. Pat. No. 6,969,993.

As described previously, the principle of pneumatic floaters is utilized when the rotor is loaded onto the detector. Therefore, a relatively small level of impact occurs when the rotor reaches and lands on the detector. However, the residual impact may deviate the position of the sample tube at which it is mounted to the rotor. If such a deviation occurs, the sample position differs from the intended position, whereby NMR measurements may be hindered.

### SUMMARY OF THE DISCLOSURE

An NMR measurement system disclosed herein comprises: a cylindrical sample tube for receiving a sample therein; a belt-like sample tube lock disposed at a given position on the outer periphery of the sample tube and protruding outwardly; a holder having a central portion provided with a vertically extending insertion space into which the sample tube is inserted, the holder acting to support a lower end of the sample tube lock in the vicinity of an upper end of the insertion space when the sample tube is inserted; a rotor extending upwardly from an upper portion of the holder, surrounding the sample tube lock and the sample tube via an interior gap, and including an inner peripheral surface that has a groove formed so as to be recessed outwardly in the vicinity of the holder; and a holder lock having a cylindrical sidewall, a top wall extending inwardly from an upper end of the sidewall and centrally provided with an insertion hole into which the sample tube is inserted, and a flange portion extending outwardly from its outer peripheral portion at a lower end of the sidewall. The outer peripheral portion of the flange portion is received in the groove and secured to the rotor.

The outer periphery of the sidewall of the holder lock has an outside diameter that decreases in going upwardly. The outer periphery of the sidewall has an inside diameter that is greater than the outside diameter of an upper portion of the holder lock and smaller than the outside diameter of a lower portion. The flange portion may be moved inwardly from the groove by inserting a pipelike jig into the interior gap around the sidewall of the holder lock.

The holder and the rotor are made from separate members. The rotor has a holder-receiving hole into which the holder is inserted. The upper end of the holder has a holder flange portion extending outwardly. The lower surface of the holder flange portion is supported by the upper surface of the rotor in the vicinity of the holder-receiving hole. The holder may be movable upwardly from the holder-receiving hole in the rotor.

In the holder lock, the sidewall and the flange portion may be each provided with a plurality of cutout portions extending vertically.

The NMR measurement system of the present disclosure makes it possible to prevent the position of mounting of the sample tube to the rotor from deviating due to an impact produced when the rotor arrives and sits on the detector.

### BRIEF DESCRIPTION OF THE DRAWINGS

FIG. 1 is a cross-sectional view showing the configurations of main portions of a detector included in an NMR measurement system associated with the present disclosure.

FIG. 2 is a cross-sectional view showing the configurations of sample tube-holding portions of a rotor and of a holder.

FIG. 3 is a perspective view of a holder lock 50.

FIG. 4A is a perspective view showing the configuration of a jig 70.

FIG. 4B shows a state in which the jig 70 has been halfway inserted.

FIG. 4C shows a state in which the jig 70 has been inserted to its lowest position.

### DESCRIPTION OF NON-LIMITING EMBODIMENTS

Embodiments of the present disclosure are hereinafter described with reference to the drawings. It is to be understood that the embodiments provided below are not intended to unduly restrict the present disclosure and that any configuration consisting of a combination of selected ones of examples is also embraced in the present disclosure.

### (1) System Configuration

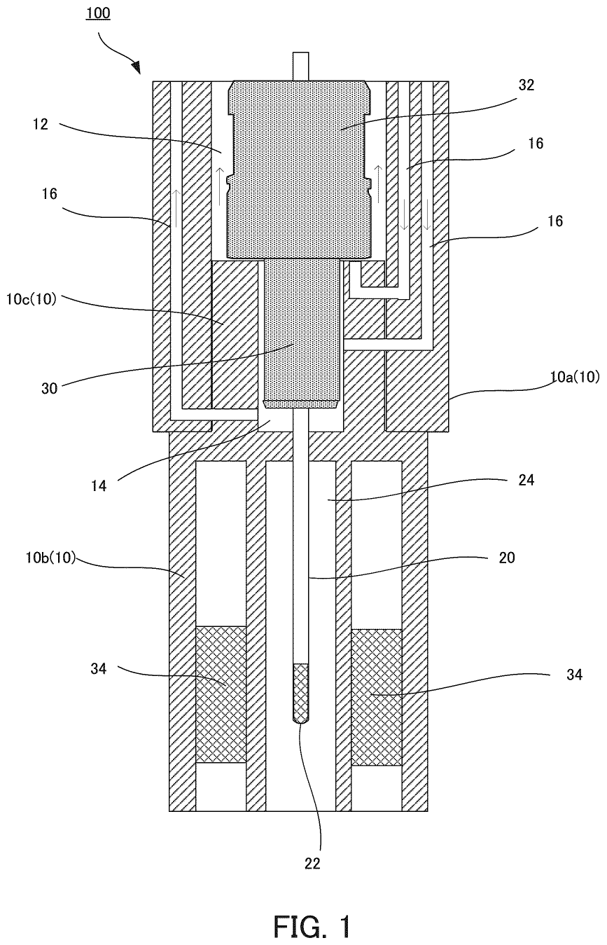

In FIG. 1, an NMR measurement system associated with the present disclosure includes a detector 100, the configurations of main portions of the detector 100 being shown in cross section in this FIG. 1. The detector 100 has a housing 10 in hollow cylindrical form. An NMR detection module 18 also in hollow cylindrical form is mechanically connected to the underside of the housing 10. The housing 10 and the detection module 18 may be formed integrally. The housing 10 is greater in diameter than the detection module 18 and internally has a cylindrical space 12. The NMR detection module 18 has an upper end portion on which a protrusion 18c of a relatively small diameter is formed. The housing 10 has a lower end which surrounds the protrusion 18c of the detection module 18 and which is connected to an annular region at the peripheral fringes of the protrusion 18c. The protrusion 18c has an internal, cylindrical storage space 14. The housing 10 and the detection module 18 are each provided with a plurality of air passages 16 for circulation of air.

The sample tube 20 is a long cylindrical pipe and has a given portion (lower end portion, in this example) in which the sample 22 is received. After the sample 22 is received in the sample tube 20, the tube is closed and sealed up, whereby the sample 22 is sealed in. The sample tube 20 has an upper portion held to both the holder 30 and a rotor 32 both of which are cylindrical in form. In this example, the rotor 32 and the holder 30 are made from separate members, and the holder 30 is secured to a lower portion of the rotor 32. Alternatively, the rotor 32 and the holder 30 may be formed integrally. The rotor 32 is greater in diameter than the holder 30. The bottom surface of the rotor 32 is spread annularly around the upper end of the holder 30. The holder 30 and the rotor 32 can be made of fluororesins or the like.

The rotor 32 and the holder 30 are received in the cylindrical space 12 and the storage space 14, respectively. The annular lower surface of the rotor 32 located around thee holder 30 is supported by the annular upper end of the protrusion 18c.

The sample tube 20 extends further downwards from the lower end of the holder 30. A placement space 24 in the form of a cylinder whose upper end is closed is formed in the center of the detection module 18. The upper wall of the placement space 24 is centrally provided with a hole into which the sample tube 20 is inserted.

A temperature control gas is circulated through the placement space 24. The temperatures around the sample tube 20 can be adjusted appropriately. Flow passages for the temperature control gas are not shown.

An NMR detector 34 for detecting NMR signals is disposed around the position of the sample 22 inside the sample tube 20 in the detection module 18. The NMR detector 34 includes a detection coil (not shown) for sending and receiving RF signals. An electrostatic field generator including superconducting coils is mounted around the housing 10.

The sample tube 20 is inserted into the hole in the upper wall of the detection module 18 while the sample tube 20 is held to both the holder 30 and the rotor 32. The rotor 32 and the holder 30 to which the sample tube 20 has been attached is moved by utilizing the principle of pneumatic floaters and lowered to the illustrated position.

In this example, the rotor 32 can be rotated by blowing air against the rotor 32 with the use of the air passages 16. This permits NMR measurements to be performed while rotating the sample tube 20. The air passages 16 can also be used to transport the sample tube 20 with a pneumatic floater.

The sample 22 is placed in position relative to the NMR detector 34 while the rotor 32 is supported to the housing 10 as shown in FIG. 1. A given static magnetic field is produced by the static magnetic field generator placed around the housing 10. Under this condition, RF signals are sent and received by the NMR detector 34. Thus, NMR signals concerning the sample 22 can be detected. Furthermore, NMR signals can be detected while rotating the sample 22 by blowing air from the air passages 16 so as to rotate the rotor 32.

### (2) Configurations of Rotor and Holder

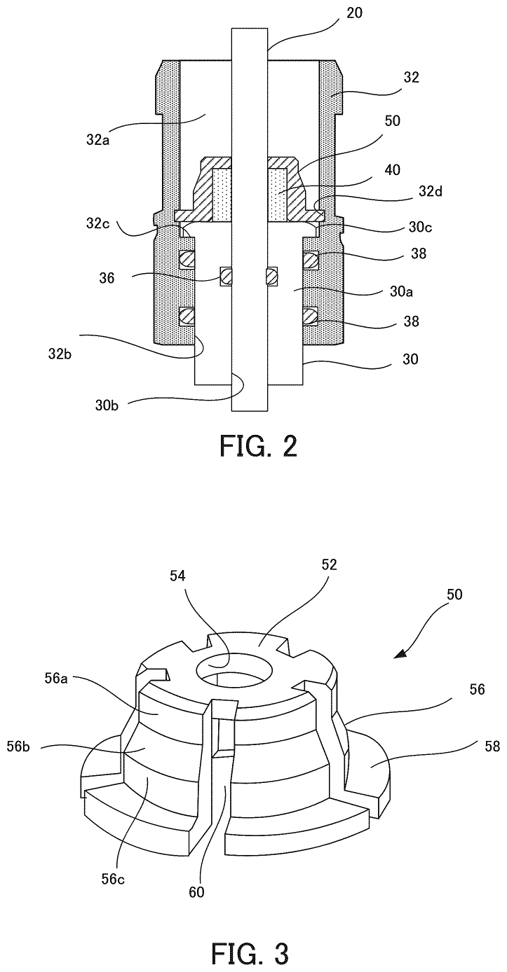

FIG. 2 is a cross-sectional view of those portions of the rotor 32 and the holder 30 which hold the sample tube 20, showing the configurations of the holding portions.

The holder 30 has a cylindrical base portion 30a. A holder flange portion 30c extending towards the surroundings is formed at the upper end of the base portion 30a. A cylindrical insertion space 30b is formed vertically in the center of the holder 30 to permit insertion of the sample tube 20 thereinto. An annular groove extending outwardly from the insertion space 30b is formed vertically midway of the insertion space 30b. An O-ring 36 is received in this groove, whereby the insertion space 30b is separated into upper and lower subspaces.

The rotor 32 is a hollow cylinder as a whole. An interior gap 32a is formed in an upper part of the cylindrical interior of the rotor 32. The rotor 32 has an inner surface having an intermediate portion where a step portion 32c is formed. The inside diameter of the rotor 32 decreases in going downwardly from the intermediate portion. The step portion 32c is an annular plane constituting the bottom surface of the interior gap 32a. A cylindrical holder-receiving hole 32b is formed in the lower portion of the rotor 32 (i.e., below the step portion 32c) and extends downwardly continuously with the interior gap 32a. Two annular grooves which are spaced from each other vertically are formed in a vertical intermediate portion of the holder-receiving hole 32b and extend outwardly from the holder-receiving hole 32b. O-rings 38 are received in the two grooves, respectively. As a result, upper and lower spaces in the holder-receiving hole 32b are separated from each other.

The holder 30 is received in the holder-receiving hole 32b of the rotor 32. The lower surface of the flange portion 30c is supported on the step portion 32c around the holder-receiving hole 32b. As described previously, the rotor 32 and the holder 30 may be built integrally.

A sample tube lock 40 is mounted at a given position in the sample tube 20. The tube lock 40 is mounted so as to surround the outer periphery of the sample tube 20 and is in the form of a cylinder or belt. The vertical position of the lock 40 is determined such that the vertical position of the sample 22 in the sample tube 20 is the position of the detected measuring region of the NMR detector 34, taking account of the vertical length of the sample tube lock 40 (see FIG. 1).

The dimensions and the material of the sample tube lock 40 are so selected that the lock 40 can be mounted with a light press fit to the sample tube 20. That is, the inside diameter of the sample tube lock 40 is slightly smaller than the outside diameter of the sample tube 20. The lock 40 may be mounted to the outer periphery of the sample tube 20 while stretched resiliently. The sample tube lock 40 may be so constructed that a viscous tape is wound on the lock to achieve a uniform outside diameter.

The sample tube lock 40 protrudes outwardly from the outer periphery of the sample tube 20. The outside diameter of the sample tube lock 40 may be set smaller than the inside diameter of a holder lock 50 (described later).

The sample tube 20 having the sample tube lock 40 attached thereon is inserted into the insertion space 30b from above to below. Since the sample tube lock 40 protrudes outwardly from the sample tube 20, the lower end surface of the lock 40 is supported by the step portion 32c on the rotor 32. Consequently, the vertical position of the sample 22 in the sample tube 20 is placed in position within the measuring region of the NMR detector 34 used for detection.

Where the sample tube 20 is mounted in the holder 30 in this way, the holder lock 50 is inserted into the interior gap 32a of the rotor 32 from above to below.

### (3) Configuration of Holder Lock

FIG. 3 is a perspective view of the holder lock 50. The holder lock 50 is in the form of a hat that opens downwardly. The lock 50 has a cylindrical sidewall 56 and a top wall 52 disposed on the upper end of the sidewall 56. The top wall 52 is centrally provided with an insertion hole 54 into which the sample tube 20 is inserted.

The cylindrical sidewall 56 has a relatively thin-walled upper portion 56a, a relatively thick-walled lower portion 56c, and an intermediate portion 56b that gradually increases in wall thickness in going downwards from the upper portion 56a toward the lower portion 56c. Alternatively, the wall thickness may be constant, and the diameter may increase in going downwards. In the illustrated example, only the intermediate portion has an inclined surface. Alternatively, the whole sidewall 56 may gradually increase in diameter in going downwards.

An annular flange portion 58 is formed on the lower end of the sidewall 56 and protrudes outwardly from the outer periphery of the sidewall 56.

A plurality of vertically extending cutouts 60 are formed in all of the fringe portion of the top wall 52, the sidewall 56, and the flange portion 58 and are spaced from each other circumferentially. In this example, five cutouts 60 are formed at regular circumferential intervals. Consequently, if a force is applied to the flange portion 58 inwardly from outside, the flange portion 58 will easily deform such that its outside diameter decreases. If the force is removed, the flange portion 58 will swell out and return to its original position.

FIG. 2 shows a state in which the holder lock 50 has been mounted to the rotor 32. An outwardly recessed, annular groove 32d is formed near the step portion 32c of the rotor 32, i.e., in its inner peripheral surface slightly above the step portion 32c. The vertical position of the groove 32d is so set that the lower end of the groove 32d is at the upper end of the holder 30 and that the width of the groove 32d (i.e., the vertical distance) corresponds to the thickness of the flange portion 58. The vertical distance of the groove 32d may be slightly greater than the thickness of the flange portion 58. The vertical distance of the groove portion 32d can be uniform in the depthwise direction. If the entrance side is made greater, the flange portion 58 will enter more easily.

The depth of the groove portion 32d as taken outwardly may be set equal to or greater than the outside diameter of the flange portion 58 when it has swollen out to prevent an inwardly directed force from being applied to the flange portion 58.

### (4) Setting of Sample Tube Onto Housing

Where an NMR measurement is performed, the sample 22 is first set in the sample tube 20. As described previously, the sample 22 is in liquid form and a given amount of the sample 22 is put into the sample tube 20.

Then, the sample tube lock 40 is set on the sample tube 20. For example, the sample tube lock 40 is set at a given vertical position by applying a force on the outer periphery of the sample tube 20 so as to fit the lock 40 to the tube 20.

The sample tube 20 is inserted into the insertion space 30b at the center of the holder 30 set on the rotor 32. The lower end of the sample tube lock 40 is supported by the upper surface of the holder 30 around the upper end of the insertion space 30b.

Under this condition, the sample tube 20 is inserted into the insertion hole 54 in the holder lock 50, and the lock 50 is moved downwardly. The lock 50 descends to the position of the sample tube lock 40, whereby the holder lock 50 receives the tube lock 40 therein.

Because the outside diameter of the flange portion 58 of the holder lock 50 is slightly greater than the inside diameter of the interior gap 32a of the rotor 32, the flange portion 58 is slightly shrunk during the insertion. For this purpose, the top wall 52 of the holder lock 50 may be pushed downwardly and moved.

As described previously, the rotor 32 is provided with the groove 32d into which the flange portion 58 at the bottom of the holder lock 50 fits. When the bottom surface of the holder lock 50 reaches the position of the surface at the top end of the holder 30 and thus the insertion is complete, the shrinking force applied to the flange portion 58 is relieved simultaneously. The flange portion 58 enters the groove 32d, and the holder lock 50 is coupled to the rotor 32.

In this example, the holder 30 is also held down by the bottom surface of the holder lock 50 and secured against the rotor 32. The holder flange portion 30c is pressed against the underlying step portion 32c of the rotor 32 by the holder lock 50.

### (5) Exchange of Sample Tube

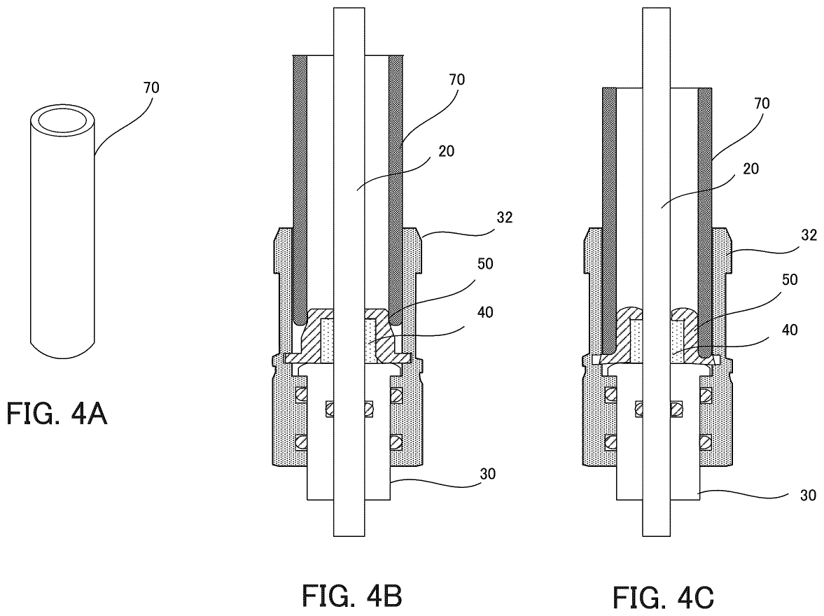

When the sample tube 20 is exchanged, a dedicated jig 70 can be used. FIG. 4A is a perspective view showing the configuration of the jig 70. FIG. 4B shows a state in which the jig 70 has been inserted over the holder lock 50. FIG. 4C shows a state in which the holder lock 50 has been inserted fully downwardly.

The jig 70 is in the form of a cylindrical pipe and has an outside diameter substantially identical to the inside diameter of the rotor 32. The inside diameter of the jig 70 is nearly equal to or slightly greater than the outside diameter of the upper portion of the holder lock 50 and is smaller than the outside diameter of the lower portion. Accordingly, by pushing the jig 70 down, the holder lock 50 is thrust inwardly. The cutouts 60 are formed in the holder lock 50. The outer side of the lower portion 56c of the sidewall 56 of the holder lock 50 moves inwardly and toward the cutouts 60 and upwardly. Consequently, the flange portion 58 of the holder lock 50 moves inwardly.

In this way, by inserting the jig 70, the flange portion 58 of the holder lock 50 can be disengaged from the groove 32d in the rotor 32, and the holder lock 50 and the rotor 32 can be uncoupled from each other. Therefore, the sample tube 20 can be detached from the rotor 32 by pulling the jig 70 and the sample tube 20 upwardly. The jig 70 can be made of a resin such as polyacetal.

The sample tube 20 can be pulled up more easily by pushing up the holder 30 from below.

1. An NMR measurement system comprising:
a cylindrical sample tube for receiving a sample therein;
a belt-like sample tube lock disposed at a given position on an outer periphery of the sample tube and protruding outwardly;
a holder having a central portion provided with a vertically extending insertion space into which the sample tube is inserted, the holder acting to support a lower end of the sample tube lock in a vicinity of an upper end of the insertion space when the sample tube is inserted;
a rotor extending upwardly from an upper portion of the holder, surrounding the sample tube lock and the sample tube via an interior gap, and comprising an inner peripheral surface that has a groove formed so as to be recessed outwardly in a vicinity of the holder; and
a holder lock having a cylindrical sidewall, a top wall disposed on an upper end of the cylindrical sidewall and centrally provided with an insertion hole into which the sample tube is inserted, and a flange portion extending outwardly from its outer peripheral portion at a lower end of the cylindrical sidewall, the outer peripheral portion of the flange portion being received in the groove and secured to the rotor.

2. The NMR measurement system according to claim 1, wherein the cylindrical sidewall of the holder lock has an outer periphery defining an outside diameter that decreases in going upwardly, and wherein the flange portion can be moved inwardly from the groove by inserting a pipelike jig into the interior gap around the cylindrical sidewall of the holder lock, the jig having an inside diameter that is greater than an outside diameter of an upper portion of the holder lock and smaller than an outside diameter of a lower portion of the holder lock.

3. The NMR measurement system according to claim 1, wherein:
the holder and the rotor are made from separate members;
the rotor includes a holder-receiving hole into which the holder is inserted;
the holder has an upper end portion provided with a holder flange portion extending outwardly;
the holder flange portion has a lower surface supported by an upper surface of the rotor around the holder-receiving hole; and
the holder is capable of moving upwardly from the holder-receiving hole in the rotor.

4. The NMR measurement system according to claim 1, wherein the cylindrical sidewall and the flange portion of the holder lock are each provided with a plurality of cutout portions which extend vertically.
